(19) United States
(12) Patent Application Publication
(10) Pub. No.: US 2026/0150236 A1
(43) Pub. Date: May 28, 2026

(54) SYSTEM AND METHOD FOR COOLING VEHICLE AUTONOMY COMPUTING SYSTEM

(71) Applicant: Torc Robotics, Inc., Blacksburg, VA (US)

(72) Inventors: Colin Butler, Salem, VA (US); Scott Pettipiece, Daleville, VA (US); Dietrich Elmon Linde, Blacksburg, VA (US)

(21) Appl. No.: 18/958,903

(22) Filed: Nov. 25, 2024

(51) Int. Cl. H05K 7/20; B60H 1/00; B60H 1/32; B60W 60/00

(52) U.S. Cl. CPC H05K 7/20272; B60H 1/00271; B60H 1/32281; H05K 7/20263; H05K 7/20281; B60H 2001/00307; B60W 60/00

(57) ABSTRACT

A system includes a heat exchanger coupled to a first fluid loop in thermal communication with an autonomy computing system of a vehicle. The heat exchanger facilitates heat transfer from fluid in the first fluid loop to an ambient environment. The system also includes a heat pump of a second fluid loop in selective thermal communication with the first fluid loop to remove heat from the fluid in the first fluid loop. The system includes a valve coupled to the first fluid loop to regulate at least one characteristic of the fluid in the first fluid loop to regulate cooling provided by the heat exchanger or the heat pump. The system includes a controller to operate the valve and control the heat removed from the fluid in the first fluid loop by at least one of the heat exchanger or the heat pump.

### TECHNICAL FIELD

The field of the disclosure relates generally to cooling systems and, more specifically, cooling systems for autonomy computing systems of vehicles.

### BACKGROUND OF THE INVENTION

Autonomous vehicles, semi-autonomous vehicles, non-autonomous vehicles, and smart vehicles may include autonomy computing systems that provide information during operation of the vehicles and may at least partly operate the vehicle based on the information. For example, the sensors may include radio detection and ranging (RADAR) sensors, light detection and ranging (LiDAR) sensors, cameras, acoustic sensors, temperature sensors, or inertial navigation system (INS), and be configured to collect information regarding the environment while the vehicle is traveling. The autonomy computing system receives the information and determines operating parameters for safely operating the vehicle. Accordingly, the autonomy computing system and other parts of the vehicle generate heat that must be managed and/or removed from the systems during operation of the vehicle to ensure the system operates reliably and to increase longevity of the systems.

At least some vehicles are configured to use air-cooling to transfer heat from a heat source to the surrounding air. However, the amount of heat managed by air-cooled systems is constrained by the specific heat of the air and air cooling requires a large mass flow rate for effective heat dissipation. As a result, the air must be moved at higher flow rate to accommodate more heat generation. In addition, air-cooled systems may increase air drag due to requirements to have exposed heat exchangers; thereby reducing vehicle fuel economy efficiency. In addition, the efficiency of the air-cooled systems could be improved.

Therefore, there is a need for improved autonomy computing cooling systems which enable increased heat loads; thereby enabling increases in processing power, all the while, not negatively impacting operation of the vehicle.

This section is intended to introduce the reader to various aspects of art that may be related to various aspects of the present disclosure described or claimed below. This description is believed to be helpful in providing the reader with background information to facilitate a better understanding of the various aspects of the present disclosure. Accordingly, it should be understood that these statements are to be read in this light and not as admissions of prior art.

### SUMMARY OF THE INVENTION

In one aspect, a system for cooling an autonomy computing system of a vehicle includes a first fluid loop in thermal communication with the autonomy computing system of the vehicle. The first fluid loop defines a fluid passageway for fluid to receive heat generated by the autonomy computing system. The system also includes a heat exchanger and a heat pump of a second fluid loop in selective thermal communication with the fluid in the first fluid loop. A valve is coupled to the second fluid loop and configured to regulate at least one characteristic of a fluid in the second fluid loop. The system also includes a controller communicatively coupled to the valve. The controller is configured to receive information relating to an operating parameter of the vehicle or the system and based on the received information operate the valve to regulate the characteristic of the fluid in the second fluid loop and control the heat removed from the fluid in the first fluid loop by at least one of the heat exchanger or the heat pump.

In another aspect, a method for cooling an autonomy computing system of a vehicle includes directing a fluid through a first fluid loop in thermal communication with the autonomy computing system of the vehicle to remove heat generated by the autonomy computing system. The method further includes operating a heat exchanger to transfer heat from the fluid in the first fluid loop to an ambient environment when the fluid in the first fluid loop is directed to the heat exchanger, and operating a heat pump of a second fluid loop in selective thermal communication with the first fluid loop downstream of the heat exchanger to remove heat from the fluid in the first fluid loop when the fluid in the first fluid loop is directed to the heat pump. The method also includes receiving information relating to an operating parameter of the fluid in the first fluid loop at a controller, and operating, based on the information received at the controller, a valve coupled to the second fluid loop to regulate a characteristic of the a in the second fluid loop and control the heat removed from the fluid in the first fluid loop by at least one of the heat exchanger or the heat pump.

In yet another aspect, a method of assembling a system for cooling an autonomy computing system of a vehicle includes positioning a first fluid loop in thermal communication with the autonomy computing system such that fluid in the first fluid loop is configured to receive heat generated by the autonomy computing system. The method also includes coupling a heat exchanger to the first fluid loop to facilitate heat transfer from the fluid in the first fluid loop to the ambient environment when the fluid in the first fluid loop is directed to the heat exchanger, and coupling a heat pump of a second fluid loop to the first fluid loop. The heat pump is in selective thermal communication with the fluid in the first fluid loop and is configured to remove heat from the fluid in the first fluid loop when the fluid in the first fluid loop is directed to the heat pump. The method further includes coupling a valve to the second fluid loop, and communicatively coupling a controller to the valve. The valve is configured to regulate a characteristic of a fluid in the second fluid loop provided to at least one of the heat exchanger or the heat pump. The controller is configured to receive information relating to an operating parameter of the fluid in the first fluid loop and based on the received information operate the valve to regulate the characteristic of the fluid in the second fluid loop.

Various refinements exist of the features noted in relation to the above-mentioned aspects. Further features may also be incorporated in the above-mentioned aspects as well. These refinements and additional features may exist individually or in any combination. For instance, various features discussed below in relation to any of the illustrated examples may be incorporated into any of the above-described aspects, alone or in any combination.

### BRIEF DESCRIPTION OF DRAWINGS

The following drawings form part of the present specification and are included to further demonstrate certain aspects of the present disclosure. The disclosure may be better understood by reference to one or more of these drawings in combination with the detailed description of specific embodiments presented herein.

FIG. 1 is a schematic diagram of a vehicle;

FIG. 2 is a block diagram of a vehicle;

FIG. 3 is a schematic block diagram of a cooling system of the vehicle, the cooling system including valves, bypass lines, and a mechanically controlled valve;

FIG. 4 is a schematic block diagram of the cooling system of FIG. 3, illustrating fluid flow through the cooling system during a cooling level 1 operating state;

FIG. 5A is a schematic block diagram of the cooling system illustrating fluid flow through the cooling system during a cooling level 2 operating state;

FIG. 5B is a schematic block diagram of the cooling system illustrating fluid flow through the cooling system during a cooling level 3 operating state;

FIG. 5C is a schematic block diagram of the cooling system illustrating fluid flow through the cooling system during a cooling level 4 operating state;

FIG. 6 is a schematic block diagram of the cooling system of the vehicle, the cooling system including an electrically controlled valve;

FIG. 7 is a schematic block diagram of the cooling system illustrating fluid flow through the cooling system during a cooling level 1 operating state;

FIG. 8 is a schematic block diagram of the cooling system illustrating fluid flow through the cooling system during a cooling level 2 operating state;

FIG. 9 is a schematic block diagram of an embodiment of a cooling system for use with the autonomous vehicle shown in FIG. 1, the cooling system including a plurality of cooling loops;

FIG. 10 is a flow chart of an example method of cooling a vehicle; and

FIG. 11 is a block diagram of an example computing device.

Corresponding reference characters indicate corresponding parts throughout the several views of the drawings. Although specific features of various examples may be shown in some drawings and not in others, this is for convenience only. Any feature of any drawing may be referenced or claimed in combination with any feature of any other drawing.

### DETAILED DESCRIPTION

The following detailed description and examples set forth preferred materials, components, and procedures used in accordance with the present disclosure. This description and these examples, however, are provided by way of illustration only, and nothing therein shall be deemed to be a limitation upon the overall scope of the present disclosure.

An autonomous vehicle: An autonomous vehicle is a vehicle that operates itself to perform various operations such as controlling or regulating acceleration, braking, or steering wheel positioning, without any human intervention. An autonomous vehicle has an autonomy level of level-4 or level-5 recognized by National Highway Traffic Safety Administration (NHTSA).

A semi-autonomous vehicle: A semi-autonomous vehicle is a vehicle that performs some of the driving related operations such as keeping the vehicle in lane or parking the vehicle without human intervention. A semi-autonomous vehicle has any level of autonomy, and in embodiments, may have an autonomy level of Level-1, Level-2, Level-3, Level-4, or Level-5 recognized by NHTSA.

A non-autonomous vehicle: A non-autonomous vehicle is a vehicle that is driven by a human driver. A non-autonomous vehicle is neither an autonomous vehicle nor a semi-autonomous vehicle. A non-autonomous vehicle has an autonomy level of level-0 recognized by NHTSA.

A smart vehicle: A smart vehicle is a vehicle installed with on-board computing devices, one or more sensors, one or more controllers, or one or more internet-of-things (IoT) devices which enables the vehicle to receive or transmit data to another vehicle or a server.

Embodiments of the present application include systems and methods for cooling a vehicle. For example, during operation of the vehicle, an autonomy computing system of the vehicle generates heat. The systems and methods described herein provide efficient management of the heat generated by the autonomy computing system without negatively impacting operation of the vehicle. The systems and methods provide increased capacity for managing the increased heat generated by autonomy computing systems.

For example, embodiments of the present application include a first fluid loop having a fluid line in thermal communication with an autonomy computing system and configured to remove heat generated by the autonomy computing system. The fluid line of the first fluid loop defines a fluid passageway. A heat exchanger is coupled to the fluid line and configured to facilitate heat transfer from a fluid or coolant in the fluid passageway to an ambient environment when the fluid is directed to the heat exchanger. A heat pump or chiller includes a second fluid or refrigerant flowing through a second fluid. The heat pump or chiller is coupled to the fluid line of the first fluid loop, and is configured to regulate a temperature of the fluid in the fluid passageway when the fluid in the first fluid loop is directed to the heat pump. A valve is coupled to the fluid line of the second fluid loop and is configured to regulate a characteristic of a fluid in the second fluid loop. For example, the valve regulates a pressure and/or temperature of the fluid in the second fluid loop to control or facilitate heat removal from the fluid in the first fluid loop. Also, a controller is communicatively coupled to the valve, the heat pump, and the heat exchanger, and is configured to receive information relating to an operating parameter of the autonomous vehicle and, based on the received information, operate the valve to regulate the characteristic of the fluid in the second fluid loop. As a result, the cooling system provides an increased capacity for managing heat generated by the autonomy computing system and more efficiently manages increased heat loads. In addition, the valve provides improved control of the characteristics of the fluid in the first cooling loop and the cooling capacity of the system to provide a broader range of cooling levels and more efficiently manage cooling the autonomy computing system.

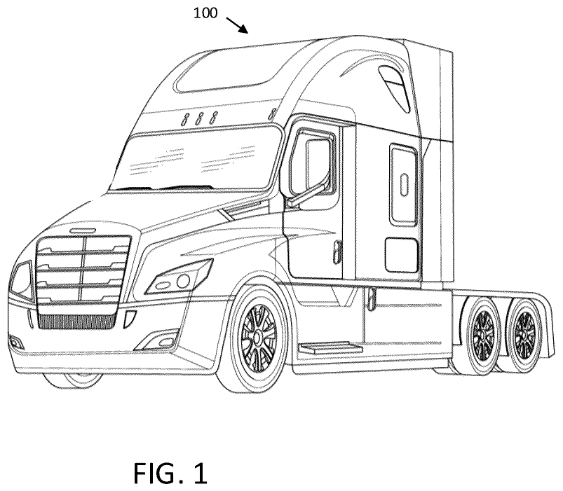

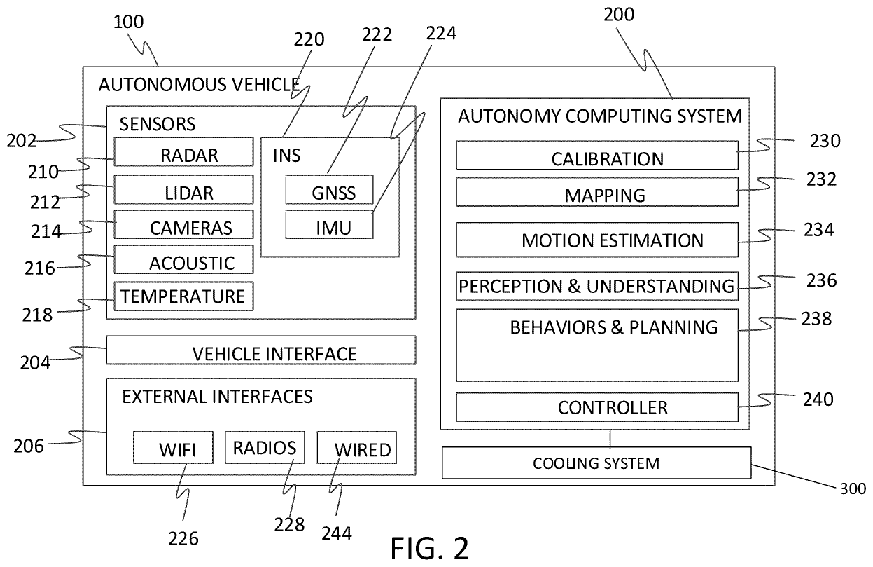

FIG. 1 is a schematic diagram of a vehicle 100. FIG. 2 is a block diagram of vehicle 100 shown in FIG. 1. In the example embodiment, vehicle 100 includes autonomy computing system 200, sensors 202, a vehicle interface 204, and external interfaces 206. For example, vehicle 100 may be an autonomous vehicle, a semi-autonomous vehicle, a non-autonomous vehicle, or a smart vehicle. In the example embodiment, vehicle 100 is an autonomous vehicle and includes autonomy computing system 200, sensors 202, a vehicle interface 204, and external interfaces 206. As described in further detail below, a cooling system 300 is configured to manage heat generated by autonomy computing system 200 and/or other components of vehicle 100.

In the example embodiment, sensors 202 may include various sensors such as, for example, radio detection and ranging (RADAR) sensors 210, light detection and ranging (LiDAR) sensors 212, cameras 214, acoustic sensors 216, temperature sensors 218, or inertial navigation system (INS) 220, which may include one or more global navigation satellite system (GNSS) receivers 222 and one or more inertial measurement units (IMU) 224. Other sensors 202 not shown in FIG. 2 may include, for example, acoustic (e.g., ultrasound), internal vehicle sensors, meteorological sensors, or other types of sensors. Sensors 202 generate respective output signals based on detected physical conditions of vehicle 100 and its proximity. As described in further detail below, these signals may be used by autonomy computing system 200 to determine how to control operation of vehicle 100.

Cameras 214 are configured to capture images of the environment surrounding vehicle 100 in any aspect or field of view (FOV). The FOV can have any angle or aspect such that images of the areas ahead of, to the side, behind, above, or below vehicle 100 may be captured. In some embodiments, the FOV may be limited to particular areas around vehicle 100 (e.g., forward of vehicle 100, to the sides of vehicle 100, etc.) or may surround 360 degrees of vehicle 100. In some embodiments, vehicle 100 includes multiple cameras 214, and the images from each of the multiple cameras 214 may be stitched or combined to generate a visual representation of the multiple cameras' FOVs, which may be used to, for example, generate a bird's eye view of the environment surrounding vehicle 100. In some embodiments, the image data generated by cameras 214 may be sent to autonomy computing system 200 or other aspects of vehicle 100, and this image data may include vehicle 100 or a generated representation of vehicle 100. In some embodiments, one or more systems or components of autonomy computing system 200 may overlay labels to the features depicted in the image data, such as on a raster layer or other semantic layer of a high-definition (HD) map.

LiDAR sensors 212 generally include a laser generator and a detector that send and receive a LiDAR signal such that LiDAR point clouds (or “LiDAR images”) of the areas ahead of, to the side, behind, above, or below vehicle 100 can be captured and represented in the LiDAR point clouds. Radar sensors 210 may include short-range RADAR (SRR), mid-range RADAR (MRR), long-range RADAR (LRR), or ground-penetrating RADAR (GPR). One or more sensors may emit radio waves, and a processor may process received reflected data (e.g., raw radar sensor data) from the emitted radio waves. In some embodiments, the system inputs from cameras 214, radar sensors 210, or LiDAR sensors 212 may be fused or used in combination to determine conditions (e.g., locations of other objects) around vehicle 100.

GNSS receiver 222 is positioned on vehicle 100 and may be configured to determine a location of vehicle 100, which it may embody as GNSS data, as described herein. GNSS receiver 222 may be configured to receive one or more signals from a global navigation satellite system (e.g., Global Positioning System (GPS) constellation) to localize vehicle 100 via geolocation. In some embodiments, GNSS receiver 222 may provide an input to or be configured to interact with, update, or otherwise utilize one or more digital maps, such as an HD map (e.g., in a raster layer or other semantic map). In some embodiments, GNSS receiver 222 may provide direct velocity measurement via inspection of the Doppler effect on the signal carrier wave. Multiple GNSS receivers 222 may also provide direct measurements of the orientation of vehicle 100. For example, with two GNSS receivers 222, two attitude angles (e.g., roll and yaw) may be measured or determined. In some embodiments, vehicle 100 is configured to receive updates from an external network (e.g., a cellular network). The updates may include one or more of position data (e.g., serving as an alternative or supplement to GNSS data), speed/direction data, orientation or attitude data, traffic data, weather data, or other types of data about vehicle 100 and its environment.

IMU 224 is a micro-electrical-mechanical (MEMS) device that measures and reports one or more features regarding the motion of vehicle 100, although other implementations are contemplated, such as mechanical, fiber-optic gyro (FOG), or FOG-on-chip (SiFOG) devices. IMU 224 may measure an acceleration, angular rate, and or an orientation of vehicle 100 or one or more of its individual components using a combination of accelerometers, gyroscopes, or magnetometers. IMU 224 may detect linear acceleration using one or more accelerometers and rotational rate using one or more gyroscopes and attitude information from one or more magnetometers. In some embodiments, IMU 224 may be communicatively coupled to one or more other systems, for example, GNSS receiver 222 and may provide input to and receive output from GNSS receiver 222 such that autonomy computing system 200 is able to determine the motive characteristics (acceleration, speed/direction, orientation/attitude, etc.) of vehicle 100.

In the example embodiment, autonomy computing system 200 employs vehicle interface 204 to send commands to the various aspects of vehicle 100 that actually control the motion of vehicle 100 (e.g., engine, throttle, steering wheel, brakes, etc.) and to receive input data from one or more sensors 202 (e.g., internal sensors). External interfaces 206 are configured to enable vehicle 100 to communicate with an external network via, for example, a wired or wireless connection, such as Wi-Fi 226 or other radios 228. In embodiments including a wireless connection, the connection may be a wireless communication signal (e.g., Wi-Fi, cellular, LTE, 5g, Bluetooth, etc.).

In some embodiments, external interfaces 206 may be configured to communicate with an external network via a wired connection 244, such as, for example, during testing of vehicle 100 or when downloading mission data after completion of a trip. The connection(s) may be used to download and install various lines of code in the form of digital files (e.g., HD maps), executable programs (e.g., navigation programs), and other computer-readable code that may be used by vehicle 100 to navigate or otherwise operate, either autonomously or semi-autonomously. The digital files, executable programs, and other computer readable code may be stored locally or remotely and may be routinely updated (e.g., automatically or manually) via external interfaces 206 or updated on demand. In some embodiments, vehicle 100 may deploy with all of the data it needs to complete a mission (e.g., perception, localization, and mission planning) and may not utilize a wireless connection or other connection while underway.

In the example embodiment, autonomy computing system 200 is implemented by one or more processors and memory devices of vehicle 100. Autonomy computing system 200 includes modules, which may be hardware components (e.g., processors or other circuits) or software components (e.g., computer applications or processes executable by autonomy computing system 200), configured to generate outputs, such as control signals, based on inputs received from, for example, sensors 202. These modules may include, for example, a calibration module 230, a mapping module 232, a motion estimation module 234, a perception and understanding module 236, a behaviors and planning module 238, a control module or controller 240. These modules may be implemented in dedicated hardware such as, for example, an application specific integrated circuit (ASIC), field programmable gate array (FPGA), or microprocessor, or implemented as executable software modules, or firmware, written to memory and executed on one or more processors onboard vehicle 100.

Autonomy computing system 200 of vehicle 100 may be completely autonomous (fully autonomous), semi-autonomous, or with any level of autonomy. In one example, autonomy computing system 200 can operate under Level 5 autonomy (e.g., full driving automation), Level 4 autonomy (e.g., high driving automation), Level 3 autonomy (e.g., conditional driving automation), Level 2 autonomy (e.g., partial driving automation), or Level 1 autonomy (e.g., driver assistance). As used herein the term “autonomous” includes fully autonomous, semi-autonomous, or having any level of autonomy.

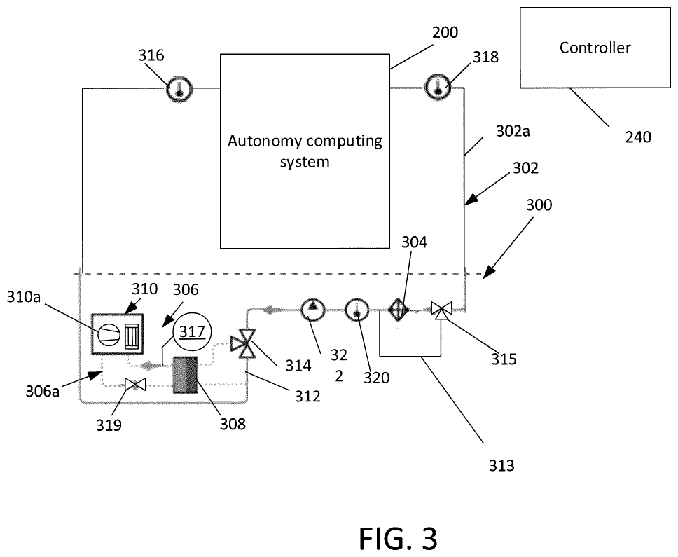

FIG. 3 is a schematic block diagram of cooling system 300 of vehicle 100. Cooling system 300 includes a first fluid loop 300 having a fluid line 302a in thermal communication with autonomy computing system 200 and configured to remove heat generated by autonomy computing system 200. Fluid line 302a defines a fluid passageway for a fluid or coolant to flow through. For example, fluid line 302a may include pipes, flexible tubing, channels, manifolds, joints, and/or any suitable components defining a fluid passageway. Fluid line 302a is arranged to receive any suitable fluid or coolant including, for example and without limitation, liquid, gas, or combinations of liquid and gas. In some embodiments, the fluid line 302a is arranged to receive a refrigerant.

The fluid in fluid line 302a receives heat generated by autonomy computing system 200 and is channeled through the fluid passageway of the first fluid loop 302 to components configured to manage the heat. In some embodiments, the fluid in the first fluid loop 302 includes glycol or another suitable refrigerant material to facilitate the heat transfer and cooling process. The fluid in fluid line 302a is returned to autonomy computing system 200 to remove additional heat from autonomy computing system 200 after flowing through the first fluid loop 302.

For example, cooling system 300 includes a heat exchanger 304 coupled to fluid line 302a of the first fluid loop 302 and configured to facilitate heat transfer from the fluid in the fluid passageway of fluid line 302a to an ambient environment when the fluid in the first fluid loop 302 is directed to heat exchanger 304. For example, heat exchanger 304 receives the heated fluid in the fluid passageway and directs the heated fluid in the first fluid loop 302 through a coil which interacts with forced air. The forced air removes heat from the fluid in the fluid passageway of the first fluid loop 302 and distributes the heat to the ambient environment.

Also, cooling system 300 includes a heat exchanger bypass 313 connected to fluid line 302a of the first fluid loop 302 upstream of heat exchanger 304 and extending downstream of heat exchanger 304. Bypass 313 is arranged for the fluid in the fluid passageway to flow past heat exchanger 304 without interacting with heat exchanger 304. For example, a valve 315 is coupled to fluid line 302 and coupled to heat exchanger bypass 313 upstream of chiller or heat pump 306. In the example, valve 315 is a three-way valve configured to selectively direct the fluid in the fluid passageway of the first fluid loop 302 to heat exchanger 304 or to heat exchanger bypass 313.

In a fail-safe state, valve 315 is configured to remain in an open position and direct the fluid in the fluid passageway to heat exchanger 304. Accordingly, in cases of failure or potential failure, valve 315 does not block flow to heat exchanger 304 and provides opportunity for cooling even if one or more systems controlling or related to valve 315 is in a compromised state.

In addition, in the example, cooling system 300 includes a chiller or heat pump system 306 coupled to fluid line 302a of the first fluid loop 302 and configured to regulate a temperature of the fluid in the fluid passageway when the fluid in the first fluid loop 302 is directed to heat pump system 306. For example, heat pump system 306 includes a second fluid loop 306a in fluid and/or in flow communication with a heat exchanger (e.g., a liquid-to-liquid heat exchanger) 308 and at least a compressor 310a of various other components 310 of the heat pump system 306 (e.g., a condenser, a dryer, etc.). Heat exchanger 308 interacts with the fluid in the fluid passageway of the first fluid loop 302 and exchanges heat between the fluid in the first fluid loop 302 and a second fluid or refrigerant flowing through the second fluid loop 306a. Compressor 310a is configured to facilitate the liquid cooling. Compressor 310a may be dedicated only to cooling system 300 and not connected to external components. For example, in some embodiments, compressor 310a is a standalone unit that only services cooling system 300 and is not connected to other components of vehicle 100 (shown in FIG. 1), such as an air conditioning system of the vehicle 100.

In some embodiments, heat pump 306 is coupled to a power source (e.g., an alternator or auxiliary power unit) on vehicle 100 (shown in FIG. 1) and receives power only from the power source. For example, in some embodiments, one or more components of cooling system 300 are belt-driven from vehicle 100. Alternatively, compressor 310a may be dual purpose and be connected to other components of vehicle 100 such as an air conditioning system.

Also, cooling system 300 includes a heat pump bypass 312 connected to fluid line 302a of the first fluid loop 302 upstream of heat pump 306 and extending downstream of heat pump 306. Heat pump bypass 312 is arranged for the fluid in the fluid passageway of the first fluid loop 302 to flow past heat pump 306 without interacting with heat pump 306. For example, valve 314 is coupled to fluid line 302a of the first fluid loop 302 and coupled to heat pump bypass 312 upstream of heat pump 306. In the example, valve 314 is a three-way valve configured to selectively direct the fluid in the fluid passageway of the first fluid loop 302 to heat pump 306 or to heat pump bypass 312. In a fail-safe state, valve 314 is configured to remain in an open position and direct the fluid in the fluid passageway of the first fluid loop 302 to heat pump 306. Accordingly, in cases of failure or potential failure, valve 314 does not block flow of the fluid in the first fluid loop 302 to heat pump 306 and provides opportunity for cooling even if one or more systems controlling or related to valve 314 is in a compromised state.

In addition, cooling system 300 includes a valve 319 coupled to the second fluid loop 306a. In one embodiment, valve 319 is an expansion valve. In other embodiments, valve 319 is any type of valve that provides sufficient control of the movement of the fluid. Expansion valve 319 is configured to regulate a characteristic of the fluid flowing through the second fluid loop 306a. For example, expansion valve 319 regulates a characteristic of the fluid in the second fluid loop 306a, which in turn, produces a change in characteristic of the fluid in the first fluid loop 302 provided to or received from at least one of heat exchanger 304 or heat pump 306. In the example, expansion valve 319 is positioned to regulate a characteristic of the fluid in the second fluid loop 306a. For example, expansion valve 319 is configured to regulate a pressure of the fluid in the second fluid loop 306a and cause the pressure of the fluid in the second fluid loop 306a to selectively rise or drop. Also, expansion valve 319 may regulate the temperature of the fluid in the first fluid loop 302. In addition, expansion valve 319 may cause the fluid in the second fluid loop 306a to change state as a result of the pressure drop/rise within expansion valve 319. The change in pressure and/or a change in temperature facilitates expansion valve 319 controlling the cooling capacity of the fluid in the first fluid loop 302 provided to and/or received from heat exchanger 304 and/or heat pump 306. In addition, expansion valve 319 ensures that the fluid in the first fluid loop 302 provided to heat pump 306 and/or heat exchanger 304 is in a state to facilitate cooling and promote heat transfer. Accordingly, expansion valve 319 regulates the fluid in the first fluid loop 302 that is provided to/received from heat pump 306 and/or heat exchanger 304 and provides precise control of the cooling provided by cooling system 300. In addition, expansion valve 319 facilitates efficient operation of cooling system 300.

In the example shown in FIG. 3, expansion valve 319 is a mechanically controlled expansion valve. For example, expansion valve 319 moves between two or more positions to change a size of the expansion valve 319 and thereby regulate a characteristic of the fluid in the second fluid loop 306a flowing through expansion valve 319. In some embodiments, the position of expansion valve 319 can be adjusted in steps to provide improved control of the characteristic of the fluid in the second fluid loop 306a and/or the first fluid loop 302.

Also, in this example, expansion valve 319 is coupled to the second fluid loop 306a upstream of the heat exchanger 308. For example, expansion valve 319 is coupled to the second fluid loop 306 a between the heat exchanger 308 and the compressor 310a(i.e., downstream of the compressor 310a and upstream of heat exchanger 308). In other embodiments, expansion valve 319 is coupled upstream of the compressor 310a or downstream of heat exchanger 308.

Cooling system 300 includes one or more components along fluid line 302a of the first fluid loop 302 to facilitate fluid flow and/or provide information relating to the flow of the first fluid through fluid line 302. For example, cooling system 300 includes a first temperature sensor 316 positioned at an inlet or upstream of autonomy computing system 200, a second temperature sensor 318 positioned at an outlet or downstream of autonomy computing system 200, and/or a third temperature sensor 320 downstream of heat exchanger 304. Temperature sensors 316, 318, 320 are arranged to measure a temperature of the fluid in fluid line 302a of the first fluid loop 302. In some embodiments, cooling system 300 includes more or less temperature sensors. For example, in some embodiments, cooling system 300 includes temperature sensors positioned immediately upstream and downstream of expansion valve 319 and configured to provide information directly to expansion valve 319 for operation of expansion valve 319. The cooling system 300 includes one or more pressure sensors 317 operably coupled to the fluid in the second fluid loop 306a to measure a pressure of the fluid in the second fluid loop 306a.

In addition, cooling system 300 includes at least one pump 322 coupled to fluid line 302a of the first fluid loop 302 and configured to cause the fluid in the first fluid loop 302 to flow through the fluid passageway defined by fluid line 302a. For example, pump 322 may be configured to direct the fluid in the first fluid loop 302 towards heat exchanger 304, valve 314, and/or heat pump 306.

Controller 240 is communicatively coupled to valves 314, 315, expansion valve 319, heat pump 306, and/or heat exchanger 304. Controller 240 is configured to receive information relating to an operating parameter of vehicle 100 and based on the received information operate valves 314, 315, expansion valve 319, heat pump 306, and/or heat exchanger 304. For example, controller 240 is configured to receive information such as a temperature and/or pressure of the fluid in the fluid passageway of the first fluid loop 302 from one or more temperature sensors and operate expansion valve 319 based on the received information to regulate a characteristic of the fluid in the second fluid loop 306a and regulate a characteristic of the fluid in the first fluid loop 302 in thermal communication with the fluid in the second fluid loop 306a. Additionally, controller 240 operates expansion valve 319 to regulate the characteristic of the fluid in the second fluid loop 306a and control the level of cooling provided by heat exchanger 304 and/or heat pump 306.

Also, in the example, controller 240 is configured to receive information relating to an operating parameter of vehicle 100 (shown in FIG. 1) and based on the received information actuate valve 314 to direct the fluid in the fluid passageway of the first fluid loop 302 to heat pump 306 or to heat pump bypass 312 and/or actuate valve 315 to direct the fluid in the fluid passageway of the first fluid loop 302 to heat exchanger 304 or the heat exchanger bypass 313. In addition, controller 240 is configured to operate heat pump 306 and/or heat exchanger 304 to manage heat carried by the fluid in fluid line 302a of the first fluid loop 302. For example, in some embodiments, the operating parameter includes a temperature of the ambient environment around vehicle 100 or a temperature of the fluid in the fluid passageway of the first fluid loop 302. For example, controller 240 may be configured to receive a temperature of the ambient environment around vehicle 100 from temperature sensor 218 shown in FIG. 2.

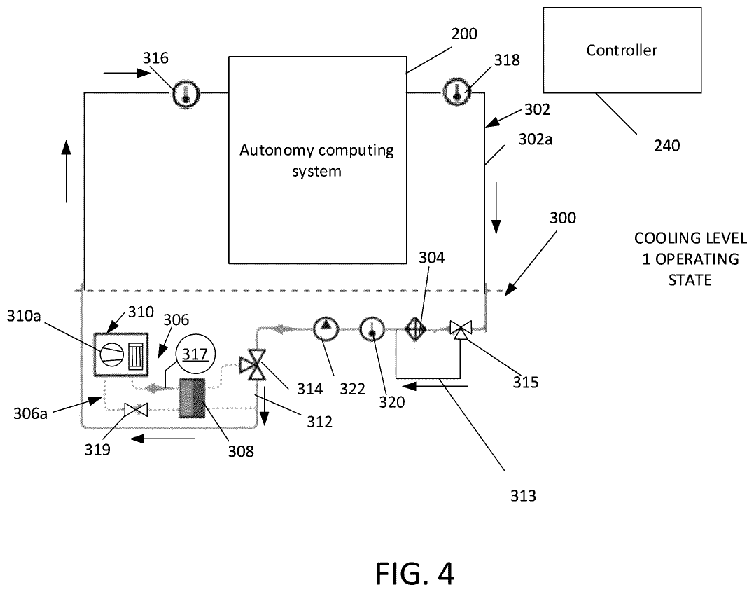

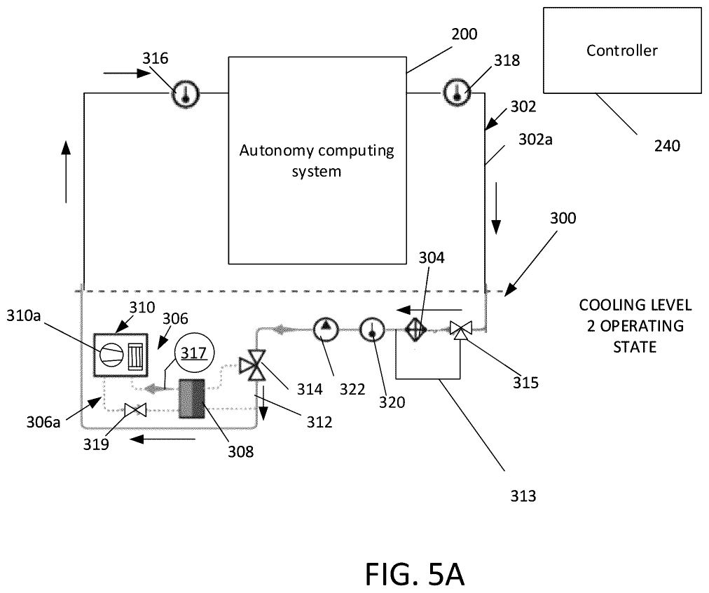

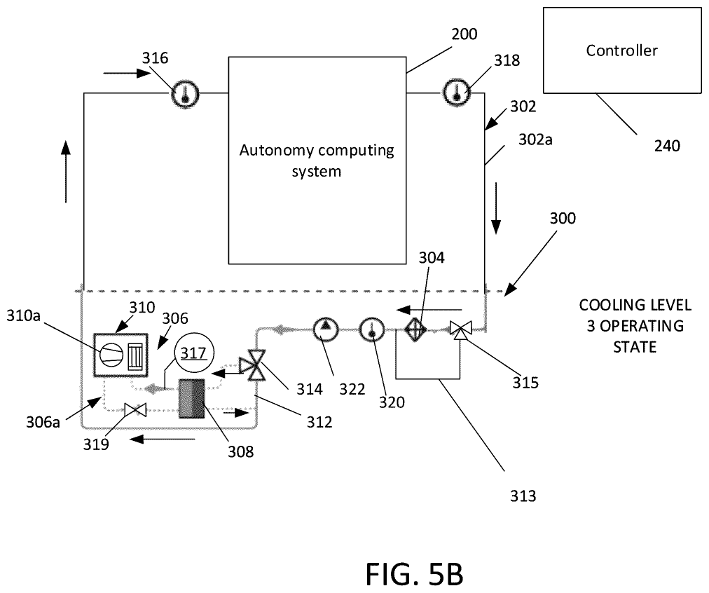

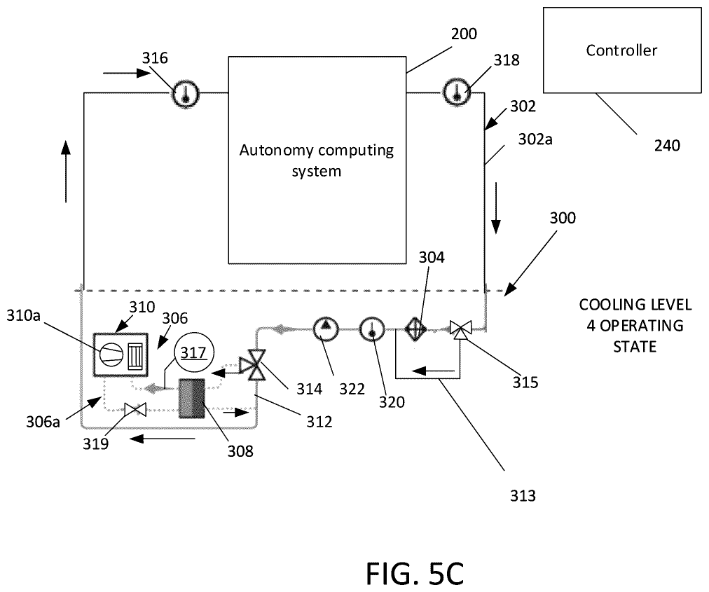

In the example embodiment, controller 240 is configured to compare the temperature to a first threshold value and a second threshold value and controller 240 operates the cooling system 300 based on the comparison. For example, if the temperature is below the first threshold value (e.g., cooling level 1 or a first state, shown in FIG. 4), controller 240 operates valve 315 to direct the fluid in the first fluid loop 302 into heat exchanger bypass 313 and beyond heat exchanger 304 without the fluid in the first fluid loop 302 interacting with heat exchanger 304 or the heat exchanger 308. If the temperature is at or above the first threshold value (e.g., cooling level 2 or a second state, shown in FIG. 5A), the controller 240 is configured to operate the valve 315 to direct the fluid in the first fluid loop 302 through the heat exchanger 304 to remove heat from the fluid in the fluid passageway of the first fluid loop 302 and bypass the heat exchanger 308. If the temperature is at or above the second threshold value (e.g., cooling level 3 or a third state, shown in FIG. 5B), controller 240 is configured to actuate valves 314 and 315 to direct the fluid in the first fluid loop 302 to the heat exchanger 304 and to the heat exchanger 308 of the heat pump 306. If the temperature is below the second threshold value (e.g., cooling level 3 or a fourth state, shown in FIG. 5C), controller 240 operates valve 314 to direct the fluid in the first fluid loop 302 to the heat exchanger 308 and operates valve 315 to direct the fluid in the first fluid loop 302 into heat exchanger bypass 313 and beyond heat exchanger 304 without the fluid in the first fluid loop interacting with the heat exchanger 304. In the example, valve 314 and heat pump 306 are coupled to fluid line 302a of the first fluid loop 302 downstream of heat exchanger 304 such that fluid in the first fluid loop 302 flows from heat exchanger 304 toward heat pump 306 when valve 314 is positioned to direct the fluid in the first fluid loop 302 toward heat pump 306.

In the example embodiment, cooling system 300 includes heat exchanger 304 and heat pump 306. In other embodiments, cooling system 300 includes any suitable cooling components. In addition, cooling system 300 is not limited to use with a vehicle. For example, in some embodiments, cooling system 300 includes or is incorporated into a refrigeration system, a heat pump system, and/or a heat extraction system.

FIG. 4 is a schematic block diagram of cooling system 300 illustrating the fluid flow of fluid in the first fluid loop 302 through cooling system 300 during a cooling level 1 operating state. Cooling level 1 operating state occurs when a temperature of the ambient environment around vehicle 100 and/or a temperature of the fluid in fluid line 302a of the first fluid loop 302 is at or below a threshold value.

When cooling system 300 operates in cooling level 1 operating state, fluid in fluid line 302a of the first fluid loop 302 interacts with autonomy computing system 200 and receives heat generated by autonomy computing system 200. Controller operates valve 315 to direct the fluid in the first fluid loop 302 into heat exchanger bypass 313 and beyond heat exchanger 304 without the fluid in the first fluid loop 302 interacting with heat exchanger 304. Heat exchanger 304 is in an Off state during cooling level 1 operating state. The controller operates valve 314 to direct the fluid in the first fluid loop 302 into the heat pump bypass 312 and beyond the heat pump 306 without the fluid in the first fluid loop 302 interacting with the heat exchanger 308.

FIG. 5A is a schematic block diagram of cooling system 300 illustrating the flow of fluid in the first fluid loop 302 through cooling system 300 during a cooling level 2 operating state. Cooling level 2 operating state occurs when the temperature of the ambient environment around vehicle 100 and the temperature of the fluid in fluid line 302a of the first fluid loop 302 is at or above the threshold value.

When cooling system 300 operates in cooling level 2 operating state, fluid in fluid line 302a interacts with autonomy computing system 200 and receives heat generated by autonomy computing system 200. The heated fluid in the first fluid loop 302 is directed to heat exchanger 304 and controller 240 operates heat exchanger 304 to remove heat from the fluid in the first fluid loop 302. After interacting with heat exchanger 304, the controller 240 operates valve 314 to direct the fluid in the first fluid loop 302 into the heat pump bypass 312 and beyond the heat pump 306 without the fluid in the first fluid loop 302 interacting with the heat exchanger 308.

When cooling system 300 operates in cooling level 3 operating state (shown in FIG. 5B), fluid in the fluid line 302a interacts with autonomy computing system 200 and receives heat generated by autonomy computing system 200. The heated fluid in the first fluid loop 302 is directed to the heat exchanger 304 and the controller 240 operates the heat exchanger 304 to remove heat from the fluid in the first fluid loop 302. After interacting with the heat exchanger 304, the controller 240 operates the valve 314 to direct the fluid in the fluid line 302a to the heat pump 306, and controller 240 operates the heat exchanger 308 to remove heat from the fluid in the first fluid loop 302. The controller 240 operates the expansion valve 319, or in embodiments, the expansion valve 319 is a mechanical expansion valve regulates by pressure of the fluid in the second fluid loop 306a, to regulate a characteristics of the fluid in the second fluid loop 306a, which in turn, regulates a characteristic of the fluid in the first fluid loop 302 via heat exchange in the heat exchanger 308. After interacting with the heat exchanger 308, the fluid in the first fluid loop 302 flows through the fluid line 302a back to the autonomy computing system 200.

When cooling system 300 operates in cooling level 4 operating state (shown in FIG. 5C), fluid in the fluid line 302a interacts with the autonomy computing system 200 and receives heat generated by the autonomy computing system 200. The heated fluid in the first fluid loop 302 is directed to the heat exchanger bypass 313 and beyond the heat exchanger 304 without the fluid in the first fluid loop 302 interacting with heat exchanger 304. The controller 240 operates the valve 314 to direct the fluid in fluid line 302a to the heat pump 306, and the controller 240 operates the heat exchanger 308 to remove heat from the fluid in the first fluid loop 302. The controller 240 operates the expansion valve 319, or in embodiments, the expansion valve 319 is a mechanical expansion valve regulates by pressure of the fluid in the second fluid loop 306a, to regulate a characteristics of the fluid in the second fluid loop 306a, which in turn, regulates a characteristic of the fluid in the first fluid loop 302 via heat exchange in the heat exchanger 308. After interacting with the heat exchanger 308, the fluid in the first fluid loop 302 flows through the fluid line 302a back to the autonomy computing system 200.

In some embodiments, cooling system 300 has a plurality of threshold values and more than two cooling level operating states. For example, expansion valve 319 may facilitate cooling system 300 having a plurality of cooling levels. For example, expansion 319 regulates a characteristic of the fluid in the second fluid loop 306a and a characteristic of the fluid in the first fluid loop 302 thermally coupled to the fluid in the second fluid loop 306a and provided to/received from heat exchanger 304 and/or heat pump 306 in increments or steps and provides continual adjustment of the cooling level of cooling system 300.

As a result, cooling system 300 provides multi-stage cooling for autonomy computing system 200 of vehicle 100. In addition, cooling system 300 provides increased efficiency and increased capacity to handle heat generated by autonomy computing system 200. Also, cooling system 300 provides less noise and vibrations than systems relying solely on air-cooling.

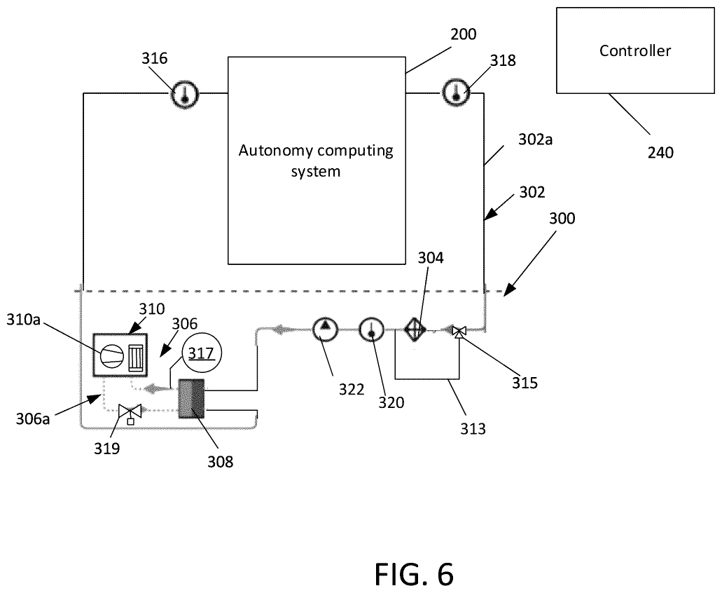

FIG. 6 is a schematic block diagram of cooling system 300 including an embodiment of expansion valve 319 that is electrically controlled. Expansion valve 319 with electrical control provides precise control of the cooling provided by cooling system 300 and facilitates efficient operation of cooling system 300 without a bypass or extra valve to control fluid in the first fluid loop 302 provided to heat pump 306. For example, expansion valve 319 is adjustable to control a pressure and/or temperature of the fluid in the first fluid loop 302 and control the level of heat removed from the fluid in the first fluid loop by at least one of heat pump 306 or heat exchanger 304. For example, expansion valve 319 provides a level of cooling of cooling system 300 from a minimum value (e.g., zero or an effective off state of heat pump 306 and/or heat exchanger 304) to a maximum value and levels between the minimum and maximum values.

In this example, expansion valve 319 is electrically controlled. For example, expansion valve 319 receives an electrical signal from controller 240 and operates based on the received signal to regulate at least one characteristic of the fluid flowing in the second fluid loop 306a, which in turn, regulates at least one characteristic of the fluid flowing in the first fluid loop 302 via heat exchange in the heat exchanger 308. The electrical signal causes expansion valve 319 to at least partially open or close and/or pulse between open and close positions. The opening and closing of expansion valve 319 changes a characteristic of the fluid in the second fluid loop 306a and can induce a pressure drop/rise in the fluid in the second fluid loop 306a, a change in temperature of the fluid in the second fluid loop 306a, and/or a change in state of the fluid in the second fluid loop 306a. Controller 240 determines desired characteristics of the fluid in the first fluid loop 302 based on information received from sensors and operates expansion valve 319 based on the received information. In the example, controller 240 determines an electrical signal and operates expansion valve 319 to adjust at least one characteristic of the flow of fluid in the second fluid loop 306a to effectuate a desired characteristics of the fluid in the first fluid loop 302 provided to heat pump 306 based on at least one of measured temperature(s) and pressure(s) of the fluid in the first fluid loop 302 and/or the second fluid loop 306a. Controller 240 operates expansion valve 319 to regulate the level of cooling provided by heat exchanger 308 and/or heat pump 306.

In the example shown in FIG. 6, expansion valve 319 may be any suitable valve that is electrically controlled. For example, expansion valve 319 may include a solenoid, a body, and an electronic controller. The solenoid, body, and electronic controller may be packaged in an assembly and/or at least a part of the electronic controller may be included in controller 240. The solenoid may operate in response to the signals provided by the controller. For example, expansion valve 319 may operate with pulse width modulation based on the signal received from the controller. In other embodiments, expansion valve 319 is operated in any suitable manner.

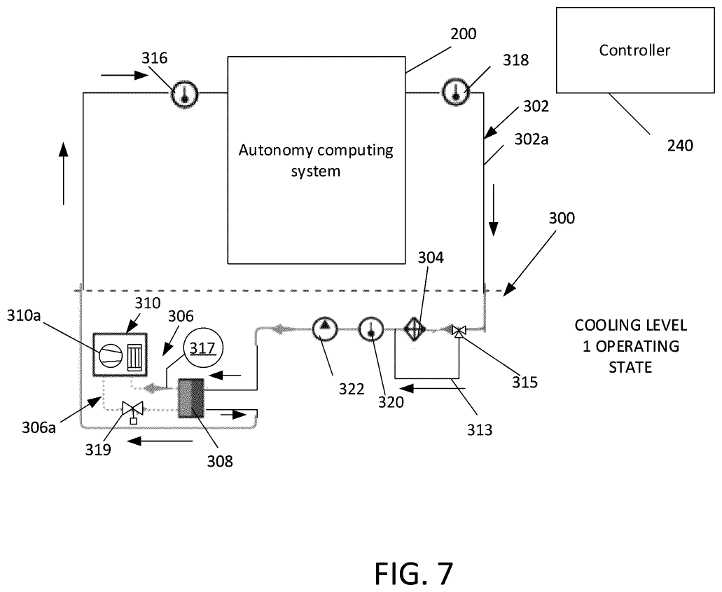

FIG. 7 is a schematic block diagram of cooling system 300 illustrating the flow of fluid in the first fluid loop 302 through cooling system 300 during a cooling level 1 operating state. Cooling level 1 operating state occurs when a temperature of the ambient environment around vehicle 100 and/or a temperature of the fluid in fluid line 302a of the first fluid loop 302 is below a threshold value.

When cooling system 300 operates in cooling level 1 operating state, fluid in fluid line 302a of the first fluid loop 302 interacts with autonomy computing system 200 and receives heat generated by autonomy computing system 200. Controller operates valve 315 to direct the fluid in the first fluid loop 302 into heat exchanger bypass 313 and beyond heat exchanger 304 without the fluid in the first fluid loop 302 interacting with heat exchanger 304. Heat exchanger 304 is in an Off state during cooling level 1 operating state. The fluid in the first fluid loop 302 flows to and through the heat exchanger 308 of the heat pump 306. Expansion valve 319 regulates a characteristic of the fluid in the second fluid loop 306a to control the level of cooling provided by heat pump 306. For example, expansion valve 319 provides additional cooling adjustments beyond the selective bypass of one or more components during cooling level 1 operating state. The fluid in the first fluid loop 302 is directed to the heat exchanger 308 of the heat pump 306 and controller 240 operates heat pump 306 to remove heat from the fluid in the first fluid loop 302. After interacting with heat pump 306, the fluid in the first fluid loop 302 flows through fluid line 302a back to autonomy computing system 200.

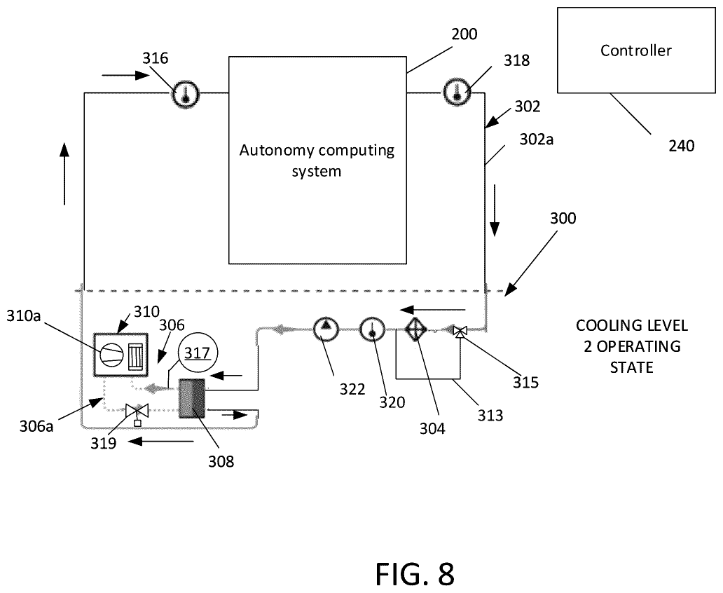

FIG. 8 is a schematic block diagram of cooling system 300 illustrating the flow of fluid in the first fluid loop 302 through cooling system 300 during a cooling level 2 operating state. Cooling level 2 operating state occurs when the temperature of the ambient environment around vehicle 100 and the temperature of the fluid in fluid line 302a of the first fluid loop 302 is at or above the threshold value.

When cooling system 300 operates in cooling level 2 operating state, fluid in fluid line 302a of the first fluid loop 302 interacts with autonomy computing system 200 and receives heat generated by autonomy computing system 200. The heated fluid in the first fluid loop 302 is directed to heat exchanger 304 and controller 240 operates heat exchanger 304 to remove heat from the fluid in the first fluid loop 302. After interacting with heat exchanger 304, the fluid in the first fluid loop 302 is directed toward the heat exchanger 308 of the heat pump 306. Controller 240 operates expansion valve 319 to regulate a characteristic of the fluid in the second fluid loop 306a which in turn, regulates a characteristic of the fluid in the first fluid loop 302 via heat transfer within the heat exchanger 308. Controller 240 is configured to operate heat pump 306 to remove heat from the fluid in the fluid passageway of the first fluid loop 302 when the fluid in the first fluid loop 302 is directed to the heat exchanger 308 of the heat pump 306. After interacting with heat pump 306, the fluid in the first fluid loop 302 flows through fluid line 302a back to autonomy computing system 200.

In some embodiments, cooling system 300 has a plurality of threshold values and more than two cooling level operating states. For example, expansion valve 319 may facilitate cooling system 300 having a plurality of cooling levels. Additionally, expansion 319 regulates a characteristic of the fluid in the second fluid loop 306a, and by extension, a characteristic of the fluid in the first fluid loop 302 provided to/received from heat exchanger 308 and/or heat pump 306 in increments or steps and provides continual adjustment of the cooling level of cooling system 300.

Referring to FIGS. 6-8, to assemble cooling system 300, fluid line 302a of the first fluid loop 302 is positioned in thermal communication with autonomy computing system 200 such that fluid in the fluid passageway of the first fluid loop 302 is configured to remove heat generated by autonomy computing system 200. Heat exchanger 308 is coupled to fluid line 302a to facilitate heat transfer from fluid in the fluid passageway of the first fluid loop 302 to the ambient environment when the fluid in the first fluid loop 302 is directed to heat exchanger 308 and heat exchanger 308 is in an ON state. Also, heat pump 306 is coupled to fluid line 302a of the first fluid loop 302 and configured to regulate a temperature of the fluid in the fluid passageway of the first fluid loop 302 when the fluid in the first fluid loop 302 is directed to the heat exchanger 308 of the heat pump 306 and heat pump 306 is in an ON state. In some embodiments, heat exchanger 308 and compressor 310a are packaged in a single unit. In other embodiments, heat exchanger 308 and compressor 310a are separate structures. For example, in some embodiments, heat pump 306 utilizes a compressor of vehicle 100 as compressor 310a and does not include a standalone compressor 310a. In other embodiments, the heat pump 306 is fluidly coupled to and/or in flow communication with an air conditioning system of the vehicle 100 and utilizes a compressor of vehicle 100 as compressor 310a and does not include a standalone compressor 310a.

Also, heat exchanger bypass 313 is connected to fluid line 302a of the first fluid loop 302 downstream of heat exchanger 304. Valve 315 is connected to fluid line 302a and to heat exchanger bypass 313. Valve 315 is arranged to selectively direct the fluid in the fluid passageway of the first fluid loop 302 to heat exchanger 304 or to heat exchanger bypass 313.

In addition, in the example shown in FIG. 3, heat pump bypass 312 is connected to fluid line 302a of the first fluid loop 302 downstream of heat pump 306. Valve 314 is connected to fluid line 302a of the first fluid loop 302 and to heat pump bypass 312. Valve 314 is arranged to selectively direct the fluid in the fluid passageway of the first fluid loop 302 to heat pump 306 or to heat pump bypass 312.

Expansion valve 319 is coupled to the second fluid loop 306a and is configured to regulate fluid within the second fluid loop 306a. For example, expansion valve 319 is coupled to the second fluid loop 306a between the heat exchanger 308 and the compressor 310a. In addition, expansion valve 319 may be coupled to one or more sensors of cooling system 300 and configured to operate based on information from the sensors.

Controller 240 is communicatively coupled to expansion valve 319, valve 314, valve 315, heat pump 306, and heat exchanger 308. Controller 240 is configured to receive information relating to an operating parameter of vehicle 100 and, based on the received information, operate expansion valve 319 to adjust at least one parameter of the fluid in the second fluid loop 306a and regulate the fluid in the first fluid loop 302 provided to the heat exchanger 308 of the heat pump 306.

In the example shown in FIG. 6, expansion valve 319 is connected to controller 240 and is configured to receive electrical signals from controller 240 for operating expansion valve 319. For example, in some embodiments, controller 240 is incorporated into or connected to an electronic controller of expansion valve 319 and causes pulsing of expansion valve 319.

In the example, pump 322 is coupled to fluid line 302 to direct the fluid in the first fluid loop 302 toward heat exchanger 308 or heat pump 306. Pump 322 may be any suitable pump and is arranged to cause fluid in the first fluid loop 302 to flow within fluid line 302 and/or heat pump bypass 312.

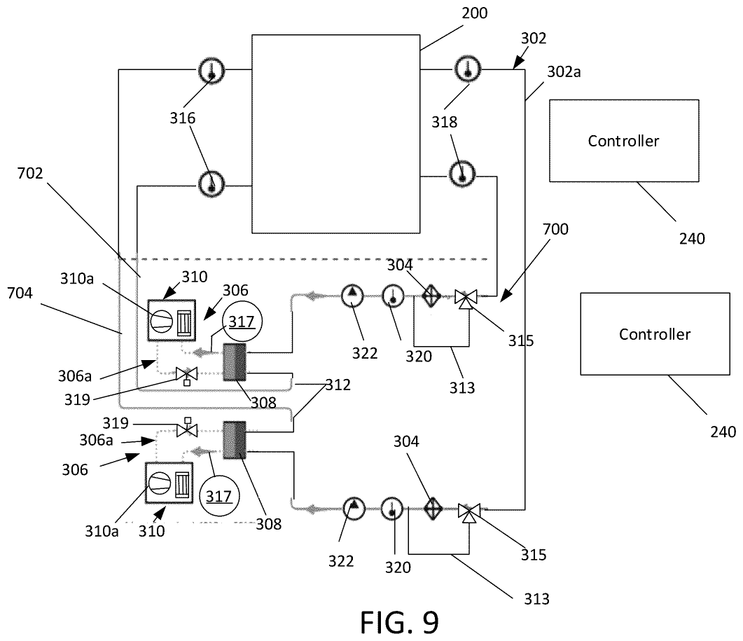

FIG. 9 is a schematic block diagram of an embodiment of a cooling system 700 for use with vehicle 100 shown in FIG. 1. Cooling system 700 is similar to cooling system 300 shown in FIGS. 3-8 except as described herein. Cooling system 700 includes a first cooling loop 702 and a second cooling loop 704. First cooling loop 702 and second cooling loop 704 provide redundant cooling loops and/or are coupled to separate portions or components of vehicle 100. In the example, first cooling loop 702 and second cooling loop 704 are coupled to autonomy computing system 200.

First cooling loop 702 and second cooling loop 704 each include fluid line 302a, heat exchanger 304, heat pump 306, heat exchanger 308, heat exchanger bypass 313, valve 315, expansion valve 319, temperature sensors 316, 318, 320 and pump 322. First cooling loop 702 and second cooling loop 704 are controlled by separate controllers 240. First cooling loop 702 and second cooling loop 704 are arranged to operate in multiple stages as described herein and may be operated in synchronization or independently of each other. In the example embodiment, first cooling loop 702 and second cooling loop 704 are entirely separated mechanically (e.g., the flow of fluid through first cooling loop 702 does not mix with the flow of fluid through second cooling loop 704) and are controlled independently by separate controllers 240.

In the example embodiment, heat pump 306 of first cooling loop 702 and heat pump 306 of second cooling loop 704 each include a separate compressor 310a. In alternative embodiments, first cooling loop 702 and second cooling loop 704 share compressor 310a. For example, compressor 310a may be dual purpose and be connected to other components of vehicle 100 and to heat exchanger 308 of first cooling loop 702 and/or heat exchanger 308 of second cooling loop 704.

First cooling loop 702 and second cooling loop 704 provide an increased capacity for managing heat generated by autonomy computing system 200. In addition, first cooling loop 702 and second cooling loop 704 may provide redundant cooling where one cooling loop provides cooling for autonomy computing system 200 if the other cooling loop is inoperable. As a result, cooling system 700 provides redundant cooling and increases the reliability of vehicle 100. For example, first cooling loop 702 or second cooling loop 704 may provide cooling to necessary components of autonomy computing system 200 and facilitate vehicle continuing traveling and/or making a safety maneuver if a portion of cooling system 700 is inoperable.

First cooling loop 702 and second cooling loop 704 each include expansion valve 319 configured to regulate a level of cooling provided by first cooling loop 702 or second cooling loops 704. Expansion valves 319 facilitate cooling system 300 providing different levels of cooling to targeted areas of autonomy computing system 200. Expansion valves 319 may be operated in synchronization with each other or independently.

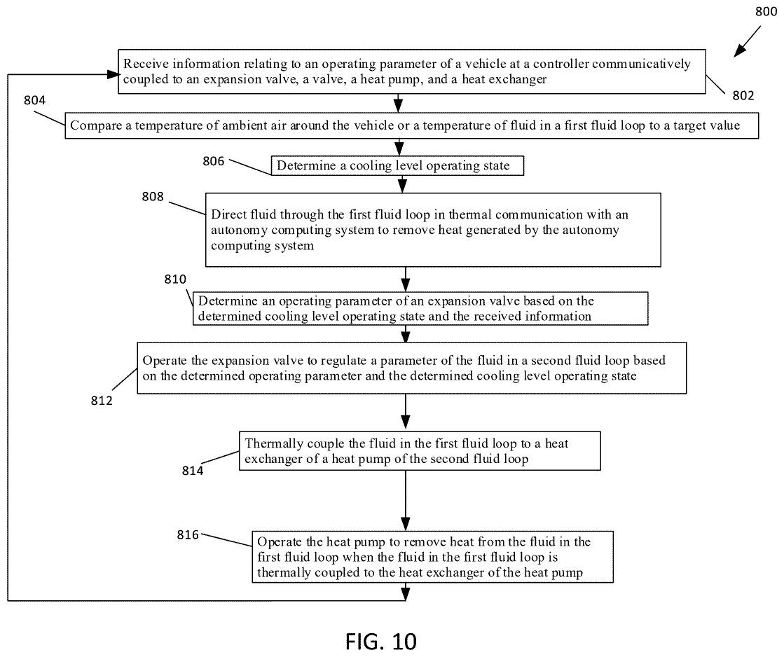

FIG. 10 is a flow chart of an example method 800 of cooling vehicle 100 using cooling system 300 (shown in FIG. 3). Referring to FIGS. 3-8 and 10, during operation of cooling system 300, controller 240 receives 802 information relating to an operating parameter of vehicle 100. For example, controller 240 receives information from sensors 202 and/or temperature sensors 316, 318, 320. Controller 240 receives information continually during operation of cooling system 300 and may change operating parameters (e.g., an operating state of cooling system 300) at any time based on the received information. For example, controller 240 operates expansion valve 319 based on the received information to regulate fluid in the second fluid loop 306a, which in turn, regulates fluid in the first fluid loop 302 provided to or otherwise thermally coupled to the heat exchanger 308 of the heat pump 306 and control a cooling level of cooling system 300. In some embodiments, controller 240 determines an initial operating state of cooling system 300 based on a temperature of ambient environment around vehicle 100 and determines subsequent operating states based on a temperature of fluid in fluid line 302a of the first fluid loop 302.

In the example embodiment, controller 240 compares 804 a temperature of ambient environment around vehicle 100 or a temperature of fluid in fluid line 302a of the first fluid loop 302 to a target value. For example, controller 240 receives temperature information from temperature sensor 218, temperature sensor 316, temperature sensor 318, and/or temperature sensor 320 and retrieves the target value retrieved from a memory. Controller 240 compares the temperature to the target value and determines 806 an operating state of cooling system 300 based on the comparison. For example, the target value may be 0° Celsius, 40° Celsius, 50° Celsius, or any suitable temperature. Controller 240 may operate using a PID process or other process in which controller 240 continuously compares the temperatures and operates cooling system 300 in increments to reach the target temperature.

For example, controller 240 operates cooling system 300 in a cooling level 1 operating state 806 if the temperature is below the target value or operates cooling system 300 in a cooling level 2 operating state 806 if the temperature is at or above the target value. For example during cooling level 1 operating state, controller 240 operates valve 315 to direct fluid in the fluid passageway of the first fluid loop 302 to heat exchanger bypass 313. The heated fluid in the first fluid loop 302 is directed through the heat exchanger bypass 313 and flows beyond heat exchanger 304. Accordingly, fluid in the first fluid loop 302 flows past heat exchanger 304 without interacting with heat exchanger 304 during cooling level 1 operating state. When cooling system 300 operates in cooling level 2 operating state, controller 240 operates valve 315 to direct fluid through the fluid passageway to heat exchanger 304 coupled to fluid line 302. Controller 240 operates heat exchanger 304 to transfer heat from the fluid in the fluid passageway to the ambient environment when the fluid is directed to heat exchanger 304.

Fluid in the first fluid loop 302 is directed 808 through the fluid passageway defined by fluid line 302a in thermal communication with autonomy computing system 200 to remove heat generated by autonomy computing system 200.

Controller 240 determines 810 an operating parameter of expansion valve 319 based on the determined cooling level state and/or information received from sensors. For example, controller 240 determines a desired cooling level and a flow provided by expansion valve 319 to heat pump 306 that will provide the desired cooling. Suitably, controller 240 continuously determines and adjusts the operating parameter of expansion valve 319 based on feedback.

Controller 240 operates 812 expansion valve 319 to regulate a parameter of the fluid in the second fluid loop 306a, and by extension, the fluid in the first fluid loop 302, based on the determined operating parameter and the determined cooling level operating state. For example, controller 240 adjusts a position (e.g., open, closed, or partially opened) of expansion valve 319 based on the determined operating parameter. The position of expansion valve 319 regulates the flow of fluid in the second fluid loop 306a to the heat exchanger 308 of the heat pump 306 and thereby regulates a cooling level of cooling system 300. Controller 240 operates 816 heat pump 306 to remove heat from the fluid in the fluid passageway of the first fluid loop 302 when the fluid in the first fluid loop 302 is directed to the heat exchanger 308 of the heat pump 306.

In some embodiments, cooling system 300 has different operating states in addition to or instead of cooling level 1 operating state and cooling level 2 operating state. For example, expansion valve 319 may be operated to provide different cooling levels based on a parameter of autonomy computing system 200 and to provide targeted cooling for autonomy computing system 200. Expansion valve 319 facilitates cooling system 300 providing precise cooling levels to efficiently accommodate cooling requirements of autonomy computing system 200.

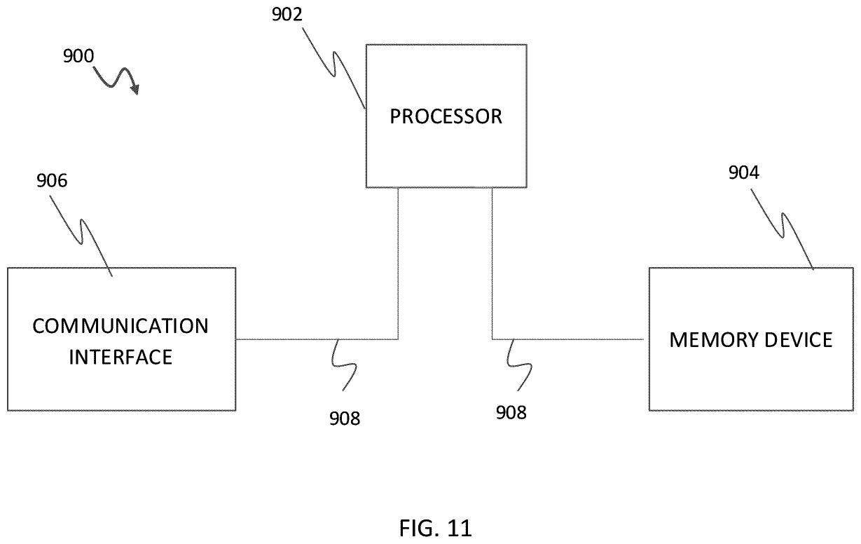

FIG. 11 is a block diagram of an example computing device 900. Computing device 900 includes a processor 902 and a memory device 904. The processor 902 is coupled to the memory device 904 via a system bus 908. The term “processor” refers generally to any programmable system including systems and microcontrollers, reduced instruction set computers (RISC), complex instruction set computers (CISC), application specific integrated circuits (ASIC), programmable logic circuits (PLC), and any other circuit or processor capable of executing the functions described herein. The above examples are example only, and thus are not intended to limit in any way the definition or meaning of the term “processor.”

In the example embodiment, the memory device 904 includes one or more devices that enable information, such as executable instructions or other data (e.g., sensor data), to be stored and retrieved. Moreover, the memory device 904 includes one or more computer readable media, such as, without limitation, dynamic random access memory (DRAM), static random access memory (SRAM), a solid state disk, or a hard disk. In the example embodiment, the memory device 904 stores, without limitation, application source code, application object code, configuration data, additional input events, application states, assertion statements, validation results, or any other type of data. The computing device 900, in the example embodiment, may also include a communication interface 906 that is coupled to the processor 902 via system bus 908. Moreover, the communication interface 906 is communicatively coupled to data acquisition devices.

In the example embodiment, processor 902 may be programmed by encoding an operation using one or more executable instructions and providing the executable instructions in the memory device 904. In the example embodiment, the processor 902 is programmed to select a plurality of measurements that are received from data acquisition devices.

In operation, a computer executes computer-executable instructions embodied in one or more computer-executable components stored on one or more computer-readable media to implement aspects of the disclosure described or illustrated herein. The order of execution or performance of the operations in embodiments of the disclosure illustrated and described herein is not essential, unless otherwise specified. That is, the operations may be performed in any order, unless otherwise specified, and embodiments of the disclosure may include additional or fewer operations than those disclosed herein. For example, it is contemplated that executing or performing a particular operation before, contemporaneously with, or after another operation is within the scope of aspects of the disclosure.

An example technical effect of the methods, systems, and apparatus described herein includes at least one of: (a) increasing capacity of cooling systems to manage heat generated by vehicles; (b) reducing noise and vibration of cooling systems for vehicles; (c) increasing the reliability of vehicles and systems for cooling vehicles; and (d) increasing the cooling efficiency of systems for cooling vehicles.

Some embodiments involve the use of one or more electronic processing or computing devices. As used herein, the terms “processor” and “computer” and related terms, e.g., “processing device,” and “computing device” are not limited to just those integrated circuits referred to in the art as a computer, but broadly refers to a processor, a processing device or system, a general purpose central processing unit (CPU), a graphics processing unit (GPU), a microcontroller, a microcomputer, a programmable logic controller (PLC), a reduced instruction set computer (RISC) processor, a field programmable gate array (FPGA), a digital signal processor (DSP), an application specific integrated circuit (ASIC), and other programmable circuits or processing devices capable of executing the functions described herein, and these terms are used interchangeably herein. These processing devices are generally “configured” to execute functions by programming or being programmed, or by the provisioning of instructions for execution. The above examples are not intended to limit in any way the definition or meaning of the terms processor, processing device, and related terms.

The various aspects illustrated by logical blocks, modules, circuits, processes, algorithms, and algorithm steps described above may be implemented as electronic hardware, software, or combinations of both. Certain disclosed components, blocks, modules, circuits, and steps are described in terms of their functionality, illustrating the interchangeability of their implementation in electronic hardware or software. The implementation of such functionality varies among different applications given varying system architectures and design constraints. Although such implementations may vary from application to application, they do not constitute a departure from the scope of this disclosure.

Aspects of embodiments implemented in software may be implemented in program code, application software, application programming interfaces (APIs), firmware, middleware, microcode, hardware description languages (HDLs), or any combination thereof. A code segment or machine-executable instruction may represent a procedure, a function, a subprogram, a routine, a subroutine, a module, a software package, a class, or any combination of instructions, data structures, or program statements. A code segment may be coupled to, or integrated with, another code segment or an electronic hardware by passing or receiving information, data, arguments, parameters, memory contents, or memory locations. Information, arguments, parameters, data, etc. may be passed, forwarded, or transmitted via any suitable means including memory sharing, message passing, token passing, network transmission, etc.

The actual software code or specialized control hardware used to implement these systems and methods is not limiting of the claimed features or this disclosure. Thus, the operation and behavior of the systems and methods were described without reference to the specific software code being understood that software and control hardware can be designed to implement the systems and methods based on the description herein.

When implemented in software, the disclosed functions may be embodied, or stored, as one or more instructions or code on or in memory. In the embodiments described herein, memory includes non-transitory computer-readable media, which may include, but is not limited to, media such as flash memory, a random access memory (RAM), read-only memory (ROM), erasable programmable read-only memory (EPROM), electrically erasable programmable read-only memory (EEPROM), and non-volatile RAM (NVRAM). As used herein, the term “non-transitory computer-readable media” is intended to be representative of any tangible, computer-readable media, including, without limitation, non-transitory computer storage devices, including, without limitation, volatile and non-volatile media, and removable and non-removable media such as a firmware, physical and virtual storage, CD-ROM, DVD, and any other digital source such as a network, a server, cloud system, or the Internet, as well as yet to be developed digital means, with the sole exception being a transitory propagating signal. The methods described herein may be embodied as executable instructions, e.g., “software” and “firmware,” in a non-transitory computer-readable medium. As used herein, the terms “software” and “firmware” are interchangeable and include any computer program stored in memory for execution by personal computers, workstations, clients, and servers. Such instructions, when executed by a processor, configure the processor to perform at least a portion of the disclosed methods.

As used herein, an element or step recited in the singular and proceeded with the word “a” or “an” should be understood as not excluding plural elements or steps unless such exclusion is explicitly recited. Furthermore, references to “one embodiment” of the disclosure or an “exemplary” or “example” embodiment are not intended to be interpreted as excluding the existence of additional embodiments that also incorporate the recited features. Likewise, limitations associated with “one embodiment” or “an embodiment” should not be interpreted as limiting to all embodiments unless explicitly recited.

Disjunctive language such as the phrase “at least one of X, Y, or Z,” unless specifically stated otherwise, is generally intended, within the context presented, to disclose that an item, term, etc. may be either X, Y, or Z, or any combination thereof (e.g., X, Y, and/or Z). Likewise, conjunctive language such as the phrase “at least one of X, Y, and Z,” unless specifically stated otherwise, is generally intended, within the context presented, to disclose at least one of X, at least one of Y, and at least one of Z.

The disclosed systems and methods are not limited to the specific embodiments described herein. Rather, components of the systems or steps of the methods may be utilized independently and separately from other described components or steps.

This written description uses examples to disclose various embodiments, which include the best mode, to enable any person skilled in the art to practice those embodiments, including making and using any devices or systems and performing any incorporated methods. The patentable scope is defined by the claims and may include other examples that occur to those skilled in the art. Such other examples are intended to be within the scope of the claims if they have structural elements that do not differ from the literal language of the claims, or if they include equivalent structural elements with insubstantial differences form the literal language of the claims.

What is claimed is:

1. A system for cooling an autonomy computing system of a vehicle, the system comprising:
a first fluid loop in thermal communication with the autonomy computing system of the vehicle, wherein a fluid in the first fluid loop receives heat generated by the autonomy computing system;
a heat exchanger coupled to the first fluid loop and configured to facilitate heat transfer from the fluid in the first fluid loop to an ambient environment when the fluid in the first fluid loop is directed to the heat exchanger;
a heat pump of a second fluid loop in selective thermal communication with the fluid in the first fluid loop and configured to remove heat from the fluid in the first fluid loop when the fluid in the first fluid loop is directed to the heat pump;
a valve coupled to the second fluid loop and configured to regulate at least one characteristic of a fluid in the second fluid loop; and
a controller communicatively coupled to the valve, wherein the controller is configured to receive information relating to an operating parameter of the vehicle or the system and based on the received information operate the valve to regulate the at least one characteristic of the fluid in the second fluid loop or at least one characteristic of the fluid in the first fluid loop, and control the heat removed from the fluid in the first fluid loop by at least one of the heat exchanger or the heat pump.

2. The system of claim 1, wherein the at least one characteristic of the fluid in the second fluid loop includes a pressure of the fluid in the second fluid loop and the at least one characteristic of the fluid in the first fluid loop includes a temperature of the fluid in the first fluid loop.

3. The system of claim 1, further comprising a heat exchanger bypass connected to the first fluid loop and extending downstream of the heat exchanger, and a valve configured to selectively direct the fluid in the first fluid loop to the heat exchanger or the heat exchanger bypass.

4. The system of claim 2, wherein the operating parameter of the vehicle includes a temperature of the ambient environment around the vehicle or a temperature of the fluid in the first fluid loop, wherein the controller is configured to operate the heat exchanger to remove heat from the fluid in the first fluid loop when the temperature is at or above a threshold value, and wherein the heat exchanger is in an Off state when the temperature is below the threshold value.

5. The system of claim 1, wherein the valve comprises an electrically controlled expansion valve that is actuated by an electrical signal received from the controller.

6. The system of claim 5, further comprising a pressure sensor connected to the second fluid loop and at least one temperature sensor connected to the first fluid loop, wherein the controller is configured to receive information from the temperature sensor and the pressure sensor and provide the electrical signal to the electrically controlled expansion valve based on the information.

7. The system of claim 1, wherein the valve comprises a mechanically controlled expansion valve that is configured to move between a first position and a second position to regulate the characteristic of the fluid in the second fluid loop flowing through the mechanically controlled expansion valve.

8. The system of claim 1, wherein the heat pump includes a liquid-to-liquid heat exchanger and a compressor, the heat pump circulating a second fluid through the liquid-to-liquid heat exchanger and the compressor.

9. The system of claim 8, wherein the compressor is connected to an air conditioning system of the vehicle.

10. The system of claim 1, further comprising at least one pump coupled to the first fluid loop and configured to direct the fluid in the first fluid loop toward the heat exchanger or the heat pump.

11. The system of claim 1, further comprising a first temperature sensor configured to measure an inlet temperature of the fluid in the first fluid loop upstream of the autonomy computing system, and a second temperature sensor configured to measure an outlet temperature of the fluid in the first fluid loop downstream of the autonomy computing system.

12. A method for cooling an autonomy computing system of a vehicle, the method comprising:
directing a fluid through a first fluid loop in thermal communication with the autonomy computing system of the vehicle to remove heat generated by the autonomy computing system;
operating a heat exchanger coupled to the first fluid loop to transfer heat from the fluid in the first fluid loop to an ambient environment when the fluid in the first fluid loop is directed to the heat exchanger;
operating a heat pump of a second fluid loop in selective thermal communication with the first fluid loop downstream of the heat exchanger to remove heat from the fluid in the first fluid loop when the fluid is directed to the heat pump.
receiving information relating to an operating parameter of the fluid in the first fluid loop at a controller; and
operating, based on the information received at the controller, a valve coupled to the second fluid loop to regulate a characteristic of the fluid in the second fluid loop and control the heat removed from the fluid in the first fluid loop by at least one of the heat exchanger or the heat pump.

13. The method of claim 12, further comprising determining a pressure of a fluid in the second fluid loop and a temperature of the fluid in the first fluid loop and operating the valve based on at least one of the determined pressure or the determined temperature.

14. The method of claim 12, wherein operating the valve coupled to the second fluid loop comprises sending an electrical signal to the valve to regulate at least one of a pressure or a temperature of the fluid in the second fluid loop, wherein the valve comprises an electrically controlled expansion valve.

15. The method of claim 12, wherein operating the valve coupled to the second fluid loop comprises operating a mechanically controlled expansion valve configured to move between a first position and a second position to regulate the characteristic of the fluid of the second fluid loop flowing through the mechanically controlled expansion valve and producing a change in characteristic of the fluid of the first fluid loop in thermal communication with the heat pump.

16. The method of claim 12, further comprising operating a valve coupled to the first fluid loop to selectively direct the fluid in the first fluid loop to the heat exchanger or to a bypass connected to the first fluid loop downstream of the heat exchanger.

17. A method of assembling a system for cooling an autonomy computing system of a vehicle, the method comprising:
positioning a first fluid loop in thermal communication with the autonomy computing system such that fluid in the first fluid loop is configured to receive heat generated by the autonomy computing system;
coupling a heat exchanger to the first fluid loop to facilitate heat transfer from the fluid in the first fluid loop to an ambient environment when the fluid in the first fluid loop is directed to the heat exchanger;
coupling a heat pump of a second fluid loop to the first fluid loop, wherein the heat pump is in selective thermal communication with the fluid in the first fluid loop and is configured to remove heat from the fluid in the first fluid loop when the fluid is directed to the heat pump;
coupling a valve to the second fluid loop, wherein the valve is configured to regulate a characteristic of a fluid in the second fluid loop; and
communicatively coupling a controller to the valve, wherein the controller is configured to receive information relating to an operating parameter of the fluid in the first fluid loop and based on the received information operate the valve to regulate the characteristic of the fluid in the second fluid loop and control the heat removed from the fluid in the first fluid loop by at least one of the heat exchanger or the heat pump.

18. The method of claim 17, further comprising connecting a compressor of the heat pump to an air conditioning system of the vehicle.

19. The method of claim 17, further comprising coupling at least one pump to the first fluid loop to direct the fluid in the first fluid loop toward the heat exchanger or the heat pump.

20. The method of claim 17, further comprising positioning a temperature sensor to measure a temperature of the fluid in the first fluid loop, and positioning a pressure sensor to measure a pressure of a fluid in the second fluid loop, wherein the valve is an electrically controlled expansion valve, and wherein the controller is configured to operate the electrically controlled expansion valve based on the measured temperature and pressure.
